(19) United States
(12) Patent Application Publication
(10) Pub. No.: US 2004/0057388 A1
(43) Pub. Date: Mar. 25, 2004

(54) Method and device for monitoring a data transmission

(76) Inventors: Andreas Kolbe, Berlin (DE); Stefan Behrens, Berlin (DE)

Correspondence Address: TEKTRONIX, INC., Francis I. Gray, MS 50-LAW, P.O. Box 500, Beaverton, OR, 97077, US

(21) Appl. No.: 10/655,807

(22) Filed: Sep. 5, 2003

(30) Foreign Application Priority Data
Sep. 11, 2002 (EP) 02020322.0

(51) Int. Cl. H04L 12/28; G01R 31/08; G08C 15/00; H04L 12/26; G06F 11/00; H04J 3/14; H04J 1/16; H04L 1/00; H04L 12/56

(52) U.S. Cl. 370/252; 370/395.1

(57) ABSTRACT

The present invention relates to a method and device for monitoring a data transmission having a plurality of physical links between two network nodes, corresponding ones of the physical links being combined to form a virtual link, with the data transmitted between the two network nodes being distributed among individual physical links and with data packets containing affiliation information about the virtual link to which the corresponding ones of the physical links belong being transmitted on the physical links between the two network nodes during the data transmission. The method and device include connecting a monitoring device to tap the plurality of physical links between the two nodes, receiving data packets transmitted on the plurality of physical links, extracting the affiliation information of the data packets, and analyzing the extracted affiliation information in order to determine the corresponding ones of the physical links that form the virtual link, all without the monitoring device having to re-transmit the data packets.

### BACKGROUND OF THE INVENTION

The present invention relates to protocol analysis, and more particularly to a method and a device for monitoring a data transmission having a plurality of physical links between two network nodes, some of which are combined to form a virtual link, with the data transmitted between the two network nodes being distributed to the individual physical links and with data packets which contain affiliation information about the virtual link to which the corresponding physical link belongs being transferred on the physical links between the two network nodes during the data transmission.

During the operation of ATM (Asynchronous Transfer Mode) links via E1 (2.048 Mb/s) or DS1 (1.544 Mb/s) lines, the bandwidth of these lines in many cases is too low. The next higher lines E3 (34.368 Mb/s) or DS3 (44.736 Mb/s) used in the PDH hierarchy, however, have too high a bandwidth for many application cases and are thus too expensive. For this, the Technical Committee of the ATM Forum offers a solution which is the “Inverse Multiplexing for ATM (IMA) Specification” (AF-PHY-0086.001). This specification describes how up to 32 physical links of a group, which are of the same kind, may be combined to form a common logical link, i.e. a virtual link, via which an ATM cell stream is then transmitted, with the cells of the ATM cell stream being evenly distributed in a round-robin method to the physical links involved.

In order to realize such a transmission, both end points of such a connection have to “know” which physical lines are combined as the group. For this, the two end points exchange special ATM cells, so-called ICP (IMA Control Protocol) cells. The set-up of the virtual link is effected with the aid of state machines. In accordance with the IMA protocol, the parameters of the IMA transmission are agreed between the two network nodes in a handshake method when the connection is set up, continuously monitored during data transmission and updated if required. For the monitoring and control of the link, ICP cells also are used. With the help of this continuous monitoring, propagation delay and bit rate differences between the individual physical links of a group may be compensated. In addition, disturbed physical links are identified with the aid of these special ATM cells. Likewise, it is possible to add to or remove from a group physical links in accordance with the bandwidth demand of an application.

To monitor complex telecommunication systems, monitoring instruments are used which evaluate the protocol information transmitted on the communication lines. With the help of such instruments it is possible to ensure that a communication between two end points corresponds to a predetermined communication protocol. Likewise, defective protocol messages as well as error cases may be found in the monitored telecommunication system.

To this end there is known from the prior art a monitoring instrument that allows active monitoring, the monitoring instrument being connected into the line to be monitored. In the case of an IMA application, the monitoring instrument itself sets up IMA links in both directions. The user data itself is then transmitted via the monitoring instrument. In this known solution the monitoring instrument becomes part of the telecommunication system. The disadvantage of this solution is that the ATM cells transmitted on the individual physical lines have to be distributed anew in the monitoring instrument to the physical lines, which then only enables falsified statements on propagation delays as well as falsified analysis results. Moreover, in the receiver of the monitoring instrument propagation delay differences between the individual physical lines are compensated. In the monitoring instrument this also causes a delay of the information to be transmitted. According to the IMA specification, propagation delay differences of 25 ms need to be compensated as a minimum. This, too, leads to a falsification of the monitoring results.

Therefore, what is desired is to further develop a generic method and a generic device in such a way that a more accurate, non-invasive and also a unidirectional monitoring is made possible.

### BRIEF SUMMARY OF THE INVENTION

Accordingly the present invention is based on the realization that a monitoring instrument may be connected passively to the lines to be monitored if the instrument appropriately analyses the ICP cells transmitted on the lines according to the IMA specification. In accordance with the information transmitted in the ICP cells, the instrument compiles all physical lines belonging to an IMA group. For this purpose, there may be used a suitable selection of the information which is transmitted in an ICP cell and which is classified as B and C in the IMA standard. If all physical lines belonging to an IMA group are connected to the instrument, the instrument compensates the propagation delay differences between the individual physical lines of an IMA group in order to assemble the ATM cells received on the individual lines into an ATM cell stream, the ATM cell sequence of which corresponds to the transmission sequence. The ATM cell streams of all IMA groups recognised by the instrument, which are received by the monitoring instrument, are then made available at an interface for further processing. As soon as the instrument has reached this state, it follows all changes in the recognised IMA groups the way they are described in the IMA specification. The monitoring instrument follows, for example, when physical lines are added or removed within an IMA group. Likewise, the instrument recognizes disturbed or interrupted physical links. The ATM cell stream at the interface for further processing is not affected by this in accordance with the IMA specification.

The special advantage of the solution according to the present invention is that the information transmitted on the lines of a telecommunication system is not affected by the monitoring. Likewise, it is a big advantage that the monitoring instrument can find the IMA groups, i.e., the virtual links, in links which are already active. It is not necessary to pick up the set-up of an IMA group between two end points.

In a first advantageous embodiment of the method according to the present invention, the extracted affiliation information is therefore analyzed in a further step in order to detect the addition of a physical link to a virtual link. Also worthy of consideration is to analyze, in a further step, the extracted affiliation information in order to recognize the removal of a physical link from a virtual link.

If a bi-directional data transmission, which is compellingly necessary for regular IMA connections, occurs between the two network nodes such that a first virtual link from the first to the second network node has the same affiliation information as a second virtual link from the second to the first network node, then an advantageous embodiment of the present invention is characterized by the fact that physical links on which data are transmitted from the first network node to the second network node are connected to a first interface of the monitoring device, and physical links on which data are transmitted from the second network node to the first network node are connected to a second interface of the monitoring device. If, however, the virtual links are agreed under the premise that different virtual links carry different affiliation information, then the physical links that belong to different virtual links may be connected to a single interface of the monitoring instrument. This is because owing to the different affiliation information a clear assignment is possible.

In case a bi-directional data transmission takes place between the two network nodes, such that the first virtual link from the first to the second network node has the same affiliation information as the second link from the second to the first network node, the data being encoded according to a transfer protocol having several layers and being transmitted on a single physical link of a virtual link not being encoded according to the highest layer, then by subdividing the affiliation information analyzing step into partial steps, a clear assignment may be achieved, even if the different physical links are connected to one and the same interface. First, a selection of physical links transmitting the same affiliation information are assigned to a virtual link. Next, at least one information channel transmitted on the virtual link is recognized, along with the information structure present there. Next, the information resulting as a consequence in a higher protocol layer is generated, and the information is analyzed to examine whether this selection of physical links actually forms the virtual link. If the result of this examination is positive, then the physical links selection made earlier may be assigned to the first virtual link. If the result of the examination is negative, the aforementioned steps are repeated with different selections of physical links until it results that the physical links forming the first virtual link have been determined. Accordingly, the physical links which transmit the same affiliation information as the first virtual link may be assigned to the second virtual link that exists between the same network nodes, but which transmits in the opposite direction to the first virtual link.

Furthermore, there is preferably transmitted in the data packets sequence information on how the data to be transmitted on the individual physical links of the virtual link are to be assembled to form a continuous data stream, with the monitoring instrument analyzing the sequence information and assembling the data streams of the individual physical links into a continuous data stream, taking account in particular of the different propagation delays, and making the continuous data stream available at an output. In the IMA method used as an example for a better understanding of the present invention, the sequence information is only transmitted for an adjustable number of cells, i.e. at every 32^{nd}, 64^{th}, 128^{th} or 256^{th} cell. These cells then constitute the ICP cells.

In the aforementioned IMA method the transmitted data packets are ATM cells, with the plurality of physical links being combined, according to the IMA method, to one or several virtual links, and the affiliation information being the information transmitted in the ICP cells and classified as B and C (status & control change indication, IMA ID group status and control, transmit timing information, link 0 information, link 1-31 information), and the sequence information being the information classified as A in the ICP cells (cell ID and link ID, IMA frame sequence number, ICP cell offset, link stuff indication).

When the data packets transmitted are analyzed by forming the information resulting in accordance with a higher protocol layer—the protocol may, for example, be AAL5—the length information for the AAL5-PDUs (Protocol Data Units) transmitted and/or the CRC32 check sum are analyzed.

In the case of protocol AAL2, the length of the payload of a CPS packet, which extends over more than one ATM cell, is compared in an advantageous manner with an offset field of a subsequent cell and/or the sequence number of ML2 cells transmitted is analyzed.

Details on the aforementioned protocols may, for example, be obtained from ITU-T Recommendation I.363.2: B-ISDN ATM Adaption Layer Specification: Type 2 AAL and ITU-T Recommendation I.363.5: B-ISDN ATM Adaption Layer Specification: Type 5 AAL.

The objects, advantages and other novel features of the present invention are apparent from the following detailed description when read in conjunction with the appended claims and attached drawing.

### BRIEF DESCRIPTION OF THE SEVERAL VIEWS OF THE DRAWING

FIG. 1 is block diagram view of a first embodiment of a device according to the present invention for monitoring a data transmission.

FIG. 2 is a block diagram view of a second embodiment of a device according to the present invention for monitoring a data transmission.

### DETAILED DESCRIPTION OF THE INVENTION

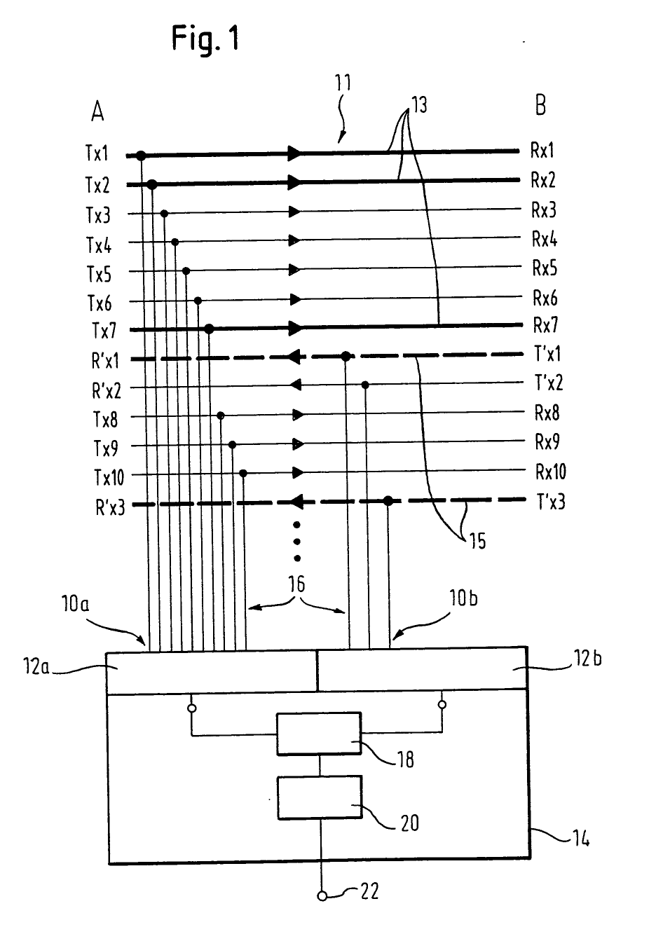

Referring now to FIG. 1 a first embodiment of a device according to the present invention is shown for monitoring a data transmission. Between two network nodes A, B there are a plurality of physical links 11. The relevant transmission side is marked Tx and T′x, respectively; the relevant receiver side is marked Rx and R′x, respectively. For an easier designation the relevant transmission and receiver connections are numbered consecutively. Between the respective transmitter and receiver there are transmitted ATM cells, the three connections 13 marked with three thick continuous lines (Tx1 Rx1, Tx2 Rx2, Tx7 Rx7) being combined to form one IMA link. Since this is the first IMA link between network nodes A and B, it is marked with the IMA ID 1. The connections 15 marked with thick dashed lines (T′x1 R′x1, T′x3 R′x3), on which there is transmission from network node B to network node A, are also combined to form an IMA link, which also carries the IMA ID 1. The physical links, on which there is transmission from network node A to network node B, are connected to a first receiver module 12a of a device 14 according to the present invention via a plurality of connections, which for uniformity reasons are marked with the reference number 10a, for monitoring a data transmission. The links from network node B to network node A are connected to the connections 10b of a receiver part 12b of the device 14. The device 14 receives signals on tap lines 16 without itself transmitting. In an extraction device 18 of device 14 the IMA ID is determined from the ICP cells received on the tap lines 16, and physical links are assigned for each receiver part 12a or 12b, which exhibit the same IMA ID, to the analysis device 20 of a single virtual link. With the aid of the link ID, which is also determined in the extraction device 18 from ICP cells received on lines 16, the signals transmitted within a virtual link may be assembled in the analysis device 20 into a continuous data stream which is made available at output 22 of the device 14.

In case that, as agreed, different IMA IDs are assigned for IMA links between the network node A and B and the network node B and A, only one of the two receiver parts 12a or 12b need to exist.

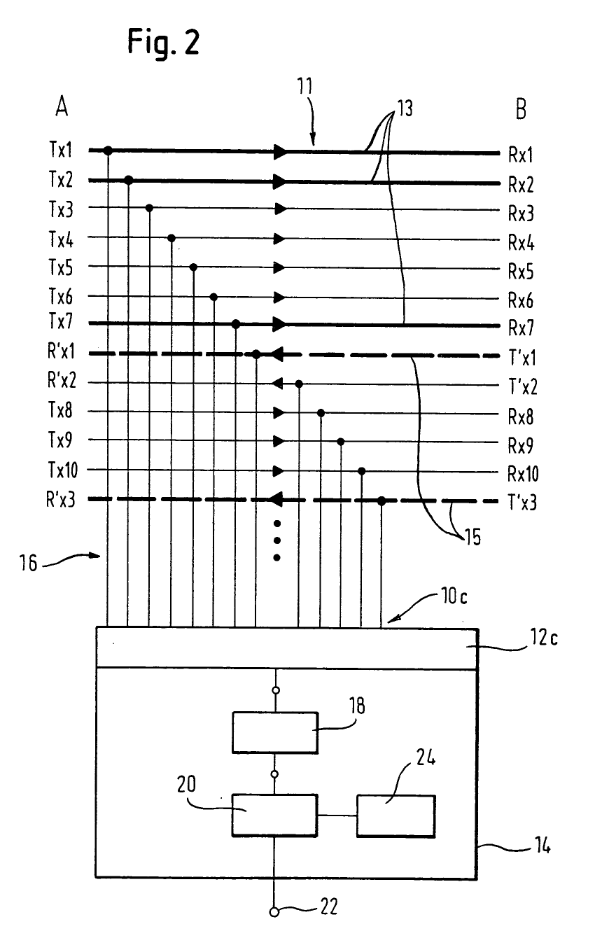

A second embodiment of a device according to the present invention for monitoring a data transmission is shown in FIG. 2. Let the links between network nodes A and B be identical to the ones of FIG. 1, also in terms of the IMA IDs, i.e. both the links Tx1 Rx1, Tx2 Rx2, Tx7 Rx7 are combined to an IMA link of the IMA ID 1, as are the links T′x1 R′x1 and T′x3 R′x3. In the embodiment shown, a receiver part 12c is envisaged which in turn exhibits a plurality of connections 10c for lines 16. In an extraction device 18 the IMA ID and the link ID of the plurality of connected physical links are again determined. In a memory device 24 there is stored information on the communication protocol used for the transmission between network nodes A and B. First, an information channel transmitted on a virtual link is recognised in the analysis device 20, as is the information structure present there. With the aid of this information there is first formed by the analysis device 20 from a first selection of physical links with an identical IMA ID the information according to a higher protocol layer, taking account of different propagation delays. Next, it is checked whether this composition provides a meaningful result. With protocol ML5, for example, length information is analyzed for the transmitted AAL5-PDUs and/or the CRC32 check sum is analyzed. With the protocol AA12, the length of the payload of a CPS packet, which extends over more than one ATM cell, may be compared with an offset field on a subsequent line and/or the sequence number of transmitted AAL2 cells may be analyzed. If a meaningful result is generated, it is assumed that the previously assumed selection of physical lines actually form the virtual link. Should the result not be meaningful, another selection of physical tap lines 16 is supplied for a corresponding analysis. This is repeated until a meaningful result is achieved and the physical links, which form a virtual link, are thus defined. Thus it is neither necessary in the case of the embodiment of FIG. 2 to have different IMA IDs agreed for IMA links from A to B and IMA links from B to A, nor is it necessary in the case of identical IMA IDs for these to be connected to different receiver parts. It is rather possible to connect the tap lines 16 to the connections 10c of the device 14 without taking any sequence into consideration.

Thus the present invention provides a method and device for monitoring a data transmission by tapping into physical links between two network nodes, by extracting affiliation information from the data packets transmitted over the physical links, and by analyzing the extracted affiliation information and optionally by analyzing the user data to determine the physical links that form each virtual link.

What is claimed is:

1. A method of monitoring a data transmission having a plurality of physical links between two network nodes, corresponding ones of the physical links being combined to form a virtual link and data transmitted between the two network nodes being distributed to the individual physical links, with data packets containing affiliation information about the virtual link to which the corresponding ones of the physical links belong being transmitted on the physical links between the two network nodes during the data transmission, comprising the steps of:
a) tapping into the physical links by connecting a monitoring device to each of the physical links;
b) receiving the data packets transmitted between the network nodes over the tapped physical links at the monitoring device;
c) extracting in the monitoring device the affiliation information from the received data packets; and
d) analyzing the extracted affiliation information to determine the corresponding ones of the physical links that are combined to form the virtual link.

2. The method according to claim 1 further comprising the step of analyzing the extracted affiliation information in order to recognise the addition of another one of the physical links to the virtual link.

3. The method according to claims 1 or 2 further comprising the step of analyzing the extracted affiliation information in order to recognise the removal of one of the corresponding ones of the physical links from the virtual link.

4. The method according claim 1 wherein in a bi-directional data transmission between the two network nodes the virtual link comprises a first virtual link from a first to a second of the network nodes having the same affiliation information as a second virtual link from the second to the first network node and further comprising the step of:
connecting the physical links from the plurality of physical links on which data are transmitted from the first network node to the second network node to a first interface of the monitoring device; and
connecting physical links from the plurality of physical links on which data are transmitted from the second network node to the first network node to a second interface of the monitoring device.

5. The method according to claim 1 in a bi-directional data transmission between the two network nodes wherein the virtual link comprises a first virtual link from a first to a second of the network nodes having the same affiliation information as a second virtual link from the second to the first network node with the data being encoded in accordance with a transfer protocol that has several layers and with the data transmitted on a single physical link of the virtual link not being encoded according to the highest layer, and wherein the analyzing step comprises the steps of:
d1) assigning a selection of the physical links which transfer the same affiliation information to the first virtual link;
d2) recognizing an information channel transmitted on the first virtual link and recognizing the information structure present there;
d3) forming the information resulting as a consequence in a higher layer;
d4) analyzing the information of the higher protocol layer in order to examine whether the selection of physical links actually form the first virtual link;
d5) if the result of this examination in step d4) is positive, assigning the selection of physical links of step d1) as the first virtual link;
d6) if the result of the examination in step d4) is negative, repeating steps d1) to d4) with different selections of physical links until the result of step d4) is that the physical links forming the first virtual link have been determined.

6. The method according to claim 5 further comprising the step of assigning the physical links which transmit the same affiliation information as the determined virtual link to the second virtual link which exists between the same network nodes but transmits in the opposite direction to the first virtual link.

7. The method according to claims 1, 2, 4, 5 or 6 further comprising the step of combining sequence information in the data packets which provides information on how the data transmitted on the individual physical links of the virtual link are assembled to form a continuous data stream; and wherein the analyzing steps comprise the steps of:
analyzing the sequence information within the monitor device;
compiling the data transmitted on the individual physical links into the continuous data stream, taking account of different propagation delays; and
making the continuous data stream available at an output.

8. The method according to claim 7 wherein the data packets are ATM cells, the plurality of physical links are combined according to the IMA specification to form the virtual link, the affiliation information is a suitable selection of information transmitted in ICP cells that are classified as B and C in the IMA specification, and the sequence information is information transmitted in the ICP cells that is classified as A in the IMA specification.

9. The method according to claim 8 wherein the transfer protocol is the AAL5 protocol and wherein in the analyzing step length information for transmitted AAL5 PDUs and/or a CRC32 check sum are analyzed.

10. The method according to claim 8 wherein the transfer protocol is the AAL2 protocol and wherein in the analyzing step the length of a payload of a CPS packet, which extends over more than one ATM cell is compared with an offset field of a subsequent cell and/or a sequence number is analyzed by transmitted AAL2 cells.

11. The method according to claim 1 wherein the data packets are ATM cells, the plurality of physical links are combined according to the IMA specification to form the virtual link, the affiliation information is a suitable selection of information transmitted in ICP cells that are classified as B and C in the IMA specification, and sequence information is information transmitted in the ICP cells that is classified as A in the IMA specification.

12. The method according to claim 5 wherein the transfer protocol is the AAL5 protocol and wherein in the analyzing step length information for transmitted AAL5 PDUs and/or a CRC32 check sum are analyzed.

13. The method according to claim 5 wherein the transfer protocol is the AAL2 protocol and wherein in the analyzing step the length of a payload of a CPS packet, which extends over more than one ATM cell is compared with an offset field of a subsequent cell and/or a sequence number is analyzed by transmitted AAL2 cells.

14. A device for monitoring a data transmission over a plurality of physical links between two network nodes, corresponding ones of the physical links being combined to form a virtual link, with data transmitted between the two network nodes being distributed to individual physical links and with data packets containing affiliation information about the virtual link to which the corresponding ones of the physical links belongs being transmitted over the physical links between the two network nodes during the data transmission comprising:
a plurality of connections for tapping into the physical links;
means for receiving the data packets transmitted on the plurality of physical links via the plurality of connections;
means for extracting the affiliation information from the data packets; and
means for analyzing the extracted affiliation information to determine the corresponding ones of the physical links which are combined to form the virtual link.
